(19) United States
(12) Patent Application Publication
(10) Pub. No.: US 2019/0296076 A1
(43) Pub. Date: Sep. 26, 2019

(54) IMAGING PANEL AND METHOD FOR PRODUCING SAME

(71) Applicant: Sharp Kabushiki Kaisha, Sakai City, Osaka (JP)

(72) Inventor: Katsunori MISAKI, Yonago-shi (JP)

(21) Appl. No.: 16/340,407

(22) PCT Filed: Oct. 6, 2017
(86) PCT No.: PCT/JP2017/036439

§ 371 Date: Apr. 9, 2019

(30) Foreign Application Priority Data
Oct. 11, 2016 (JP) 2016-200049

(51) Int. Cl. H01L 27/146; G01T 1/20

(52) U.S. Cl. CPC H01L 27/14663; H01L 27/14689; H01L 27/14692; G01T 1/2018

(57) ABSTRACT

Provided is an X-ray imaging panel in which leakage current in a photoelectric conversion layer can be decreased, and a method for producing the same. An imaging panel 1 generates an image based on scintillation light that is obtained from X-rays transmitted through an object. The imaging panel 1 includes a thin film transistor 13 on a substrate 101; an insulating film 103 that covers the thin film transistor 13; a photoelectric conversion layer 15 that converts scintillation light into charges; an upper electrode 14b; a lower electrode 14a that is connected with the thin film transistor 13; and a protection film 142 that covers a side end portion of the lower electrode 14a.

### TECHNICAL FIELD

The present invention relates to an imaging panel and a method for producing the same.

### BACKGROUND ART

An X-ray imaging device that picks up an X-ray image with an imaging panel that includes a plurality of pixels is known. In such an X-ray imaging device, for example, projected X-rays are converted into charges by photodiodes. Converted charges are read out by thin film transistors (hereinafter also referred to as TFTs) that are caused to operate, the TFTs being provided in the pixels. With the charges being read out in this way, an X-ray image is obtained. JP-A-2013-46043 discloses such an imaging panel. The photodiode in the configuration disclosed in JP-A-2013-46043 has a PIN structure in which an n-type semiconductor layer, an i-type semiconductor layer, and a p-type semiconductor layer are laminated. On the photodiode, an upper electrode formed with a transparent conductive film is provided; and under the photodiode, a lower electrode containing a metal such as aluminum is provided.

### SUMMARY OF THE INVENTION

Incidentally, in the configuration of JP-A-2013-46043, when a photoelectric conversion layer of the PIN structure is formed, the surface of the photodiode is subjected to a cleaning treatment with use of hydrofluoric acid in some cases in order to decrease leakage current. Here, when the side surface of the lower electrode is exposed to hydrofluoric acid in the cleaning treatment, a metal such as aluminum contained in the lower electrode is dissolved. As a result, ions of the metal adhere to the side surface of the photoelectric conversion layer, and causes leakage current to be generated.

It is an object of the present invention to provide an X-ray imaging panel in which leakage current can be decreased, and a method for producing the same.

An imaging panel of the present invention with which the above-described object is achieved is an imaging panel that generates an image based on scintillation light obtained from transmitted X-rays, and the imaging panel includes: a substrate; a thin film transistor formed on the substrate; an insulating film that covers the thin film transistor; a photoelectric conversion layer that is provided on the insulating film and converts the scintillation light into charges; an upper electrode provided on the photoelectric conversion layer; a lower electrode that is provided under the photoelectric conversion layer and is connected with the thin film transistor; and a protection film that covers a side end portion of the lower electrode.

With the present invention, leakage current in the photoelectric conversion layer can be decreased.

### BRIEF DESCRIPTION OF DRAWINGS

FIG. 1 schematically shows an X-ray imaging device in an embodiment.

FIG. 2 schematically shows a schematic configuration of the imaging panel shown in FIG. 1.

FIG. 3 is an enlarged plan view showing one pixel portion of the imaging panel 1 shown in FIG. 2.

FIG. 4 is a cross-sectional view of the pixel shown in FIG. 3, taken along the line A-A.

FIG. 5A is a cross-sectional view showing a step of forming a first insulating film on a gate insulating film and a TFT formed on a substrate.

FIG. 5B is a cross-sectional view showing a step of forming a contact hole CH1 in the first insulating film shown in FIG. 5A.

FIG. 5C is a cross-sectional view showing a step of forming a second insulating film on the first insulating film shown in FIG. 5B.

FIG. 5D is a cross-sectional view showing a step of forming an opening of the second insulating film on a contact hole CH1 shown in FIG. 5C.

FIG. 5E is a cross-sectional view showing a step of forming a metal film on the second insulating film shown in FIG. 5D.

FIG. 5F is a cross-sectional view showing a step of patterning the metal film shown in FIG. 5E so as to form a lower electrode that is connected with a drain electrode through the contact hole CH1.

FIG. 5G is a cross-sectional view showing a step of forming an inorganic insulating film so that the inorganic insulating film covers with the lower electrode shown in FIG. 5F.

FIG. 5H is a cross-sectional view showing a step of forming a resist over the inorganic insulating film shown in FIG. 5G.

FIG. 5I is a cross-sectional view showing a step of etching the inorganic insulating film shown in FIG. 5H so as to form a protection film.

FIG. 5J is a cross-sectional view showing a step of removing the resist shown in FIG. 5I.

FIG. 5K is a cross-sectional view showing a step of forming an n-type amorphous semiconductor layer, an intrinsic amorphous semiconductor layer, and a p-type amorphous semiconductor layer that cover the lower electrode and the protection film shown in FIG. 5J, and forming a transparent conductive film on the p-type amorphous semiconductor layer.

FIG. 5L is a cross-sectional view showing a step of patterning the transparent conductive film shown in FIG. 5K so as to form an upper electrode.

FIG. 5M is a cross-sectional view showing a step of forming a resist so that the resist covers the upper electrode shown in FIG. 5L.

FIG. 5N is a cross-sectional view showing a state in which the n-type amorphous semiconductor layer, the intrinsic amorphous semiconductor layer, and the p-type amorphous semiconductor layer shown in FIG. 5M are patterned so as to form a photoelectric conversion layer, and a cleaning treatment with use of hydrogen fluoride is applied to the surface of the photoelectric conversion layer.

FIG. 5O is a cross-sectional view showing a state in which the resist shown in FIG. 5N is removed.

FIG. 5P is a cross-sectional view showing a step of forming a third insulating film so that the third insulating film covers the photoelectric conversion layer, the lower electrode, and the protection film shown in FIG. 5O.

FIG. 5Q is a cross-sectional view showing a step of forming an opening in the third insulating film shown in FIG. 5P.

FIG. 5R is a cross-sectional view showing a step of forming a fourth insulating film on the third insulating film shown in FIG. 5Q, and forming an opening in the fourth insulating film, so as to form a contact hole CH2.

FIG. 5S is a cross-sectional view showing a step of forming a metal film on the fourth insulating film shown in FIG. 5R.

FIG. 5T is a cross-sectional view showing a step of forming a bias line by patterning the metal film shown in FIG. 5S.

FIG. 5U is a cross-sectional view showing a step of forming a transparent conductive film so that the transparent conductive film covers the bias line shown in FIG. 5T.

FIG. 5V is a cross-sectional view showing a step of patterning the transparent conductive film shown in FIG. 5U.

FIG. 5W is a cross-sectional view showing a step of forming a fifth insulating film so that the fifth insulating film covers the transparent conductive film shown in FIG. 5V.

FIG. 5T is a cross-sectional view showing a step of forming a sixth insulating film on the fifth insulating film shown in FIG. 5W.

FIG. 6 is a cross-sectional view of an imaging panel of Embodiment 2.

FIG. 7 is a cross-sectional view showing a pixel of an imaging panel in Modification Example (1).

### MODE FOR CARRYING OUT THE INVENTION

An imaging panel according to one embodiment of the present invention is an imaging panel that generates an image based on scintillation light that is obtained from transmitted X-rays, and the imaging panel includes: a substrate; a thin film transistor formed on the substrate; an insulating film that covers the thin film transistor; a photoelectric conversion layer that is provided on the insulating film and converts the scintillation light into charges; an upper electrode provided on the photoelectric conversion layer; a lower electrode that is provided under the photoelectric conversion layer and is connected with the thin film transistor; and a protection film that covers a side end portion of the lower electrode (the first configuration).

According to the first configuration, the protection film covers a side end portion of the lower electrode. Therefore, when the photoelectric conversion layer is formed, even if, for example, a cleaning treatment with use of hydrogen fluoride is carried out with respect to the surface of the photoelectric conversion layer, the side end portion of the lower electrode is not exposed to hydrogen fluoride. Ions of a metal contained in the lower electrode therefore do not adhere to the side surface of the photoelectric conversion layer, whereby leakage current can be decreased.

The first configuration may be further characterized in further including an inorganic insulating film that covers the upper electrode, the photoelectric conversion layer, and the protection film, wherein the protection film is provided at such a position that the protection film does not overlap with the photoelectric conversion layer (the second configuration).

According to the second configuration, the protection film is not arranged so as to overlap with the photoelectric conversion layer, and the photoelectric conversion layer is covered with the inorganic insulating film. For this reason, when the photoelectric conversion layer is formed, even if the thickness of the protection film decreases due to the cleaning treatment with use of hydrogen fluoride carried out with respect to the surface of the photoelectric conversion layer, the photoelectric conversion layer is completely covered with the inorganic insulating film. This makes it unlikely that the photoelectric conversion layer would be contaminated, as compared with a case where the protection film overlaps with the photoelectric conversion layer, thereby making it possible to more surely decrease the occurrence of leakage current in the photoelectric conversion layer.

The first or second configuration may be further characterized in that the protection film is made of silicon nitride (the third configuration).

With the third configuration, the adhesiveness between the lower electrode and the protection film can be improved, while leakage current in the photoelectric conversion layer can be decreased.

The first or second configuration may be further characterized in that the protection film is made of silicon oxide (the fourth configuration).

With the fourth configuration, leakage current in the photoelectric conversion layer can be decreased.

The first or second configuration may be further characterized in that the protection film is made of silicon oxide nitride (the fifth configuration).

With the fifth configuration, leakage current in the photoelectric conversion layer can be decreased.

A method for producing an imaging panel according to one embodiment of the present invention is a method for producing an imaging panel that generates an image based on scintillation light that is obtained from X-rays transmitted through an object, and the producing method includes the steps of: forming a thin film transistor on a substrate; forming a first insulating film and a second insulating film on the thin film transistor; forming a first contact hole on a drain electrode of the thin film transistor, the first contact hole passing through the first insulating film and the second insulating film; forming a lower electrode on the second insulating film, the lower electrode being connected with the drain electrode through the first contact hole; forming a protection film that covers a side end portion of the lower electrode; forming a first semiconductor layer of a first conductive type, an intrinsic amorphous semiconductor layer, and a second semiconductor layer of a second conductive type that is opposite to the first conductive type, in the stated order, as a photoelectric conversion layer, so that the photoelectric conversion layer covers the lower electrode and the protection film; forming an upper electrode on the second semiconductor layer; applying a resist on the second semiconductor layer so that the resist covers the upper electrode, and etching the first semiconductor layer, the intrinsic amorphous semiconductor layer, and the second semiconductor layer, thereby forming the photoelectric conversion layer; and carrying out a cleaning treatment with use of hydrogen fluoride with respect to a surface of the photoelectric conversion layer formed (the first producing method).

According to the first producing method, the side end portion of the lower electrode is covered with the protection film. For this reason, even if the surface of the photoelectric conversion layer is subjected to a cleaning treatment with use of hydrogen fluoride, ions of a metal contained in the lower electrode do not adhere to the surface of the photoelectric conversion layer. As a result, an imaging panel in which leakage current in the photoelectric conversion layer is decreased can be produced.

The first producing method may be further characterized in that the protection film is provided at such a position that the protection film does not overlap with the photoelectric conversion layer, and the producing method further includes the step of forming a third insulating film after the cleaning treatment, the third insulating film covering the upper electrode, the photoelectric conversion layer, and the protection film (the second producing method).

According to the second producing method, the protection film is not arranged so as to overlap with the photoelectric conversion layer, and the photoelectric conversion layer is covered with the third insulating film. For this reason, even if the cleaning treatment with use of hydrogen fluoride is carried out with respect to the surface of the photoelectric conversion layer and the thickness of the protection film decreases due to hydrogen fluoride, the photoelectric conversion layer is completely covered with the third inorganic insulating film. This makes it unlikely that the photoelectric conversion layer would be contaminated, as compared with a case where the protection film overlaps with the photoelectric conversion layer, thereby making it possible to more surely decreased the occurrence of leakage current in the photoelectric conversion layer.

The following description describes embodiments of the present invention in detail, while referring to the drawings. Identical or equivalent parts in the drawings are denoted by the same reference numerals, and the descriptions of the same are not repeated.

### EMBODIMENT 1

### (Configuration)

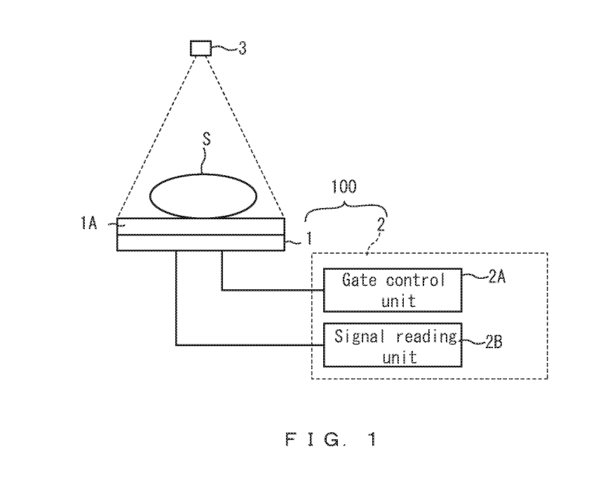

FIG. 1 is a schematic diagram showing an X-ray imaging device in the present embodiment. The X-ray imaging device 100 includes an imaging panel 1 and a control unit 2. The control unit 2 includes a gate control unit 2A and a signal reading unit 2B. X-rays are projected from the X-ray source 3 to an object S, and X-rays transmitted through the object S are converted into fluorescence (hereinafter referred to as scintillation light) by a scintillator 1A provided above the imaging panel 1. The X-ray imaging device 100 acquires an X-ray image by picking up the scintillation light with the imaging panel 1 and the control unit 2.

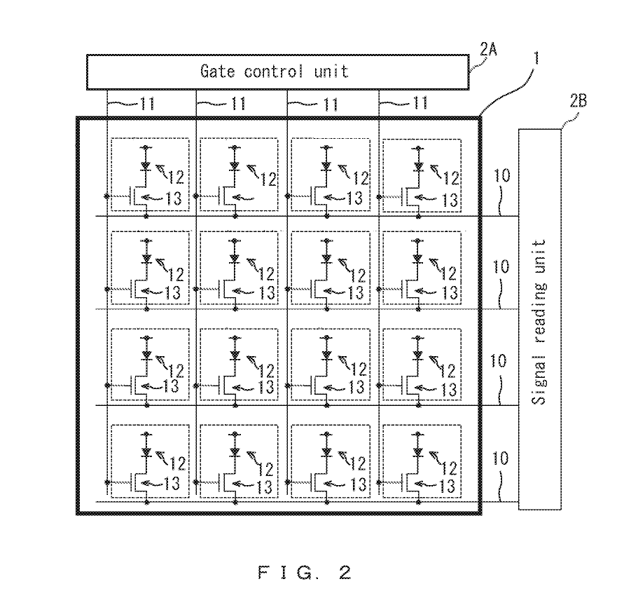

FIG. 2 is a schematic diagram showing a schematic configuration of the imaging panel 1. As shown in FIG. 2, a plurality of source lines 10, and a plurality of gate lines 11 intersecting with the source lines 10 are formed in the imaging panel 1. The gate lines 11 are connected with the gate control unit 2A, and the source lines 10 are connected with the signal reading unit 2B.

The imaging panel 1 includes TFTs 13 connected to the source lines 10 and the gate lines 11, at positions at which the source lines 10 and the gate lines 11 intersect. Further, photodiodes 12 are provided in areas surrounded by the source lines 10 and the gate lines 11 (hereinafter referred to as pixels). In each pixel, scintillation light obtained by converting X-rays transmitted through the object S is converted by the photodiode 12 into charges according to the amount of the light.

The gate lines 11 in the imaging panel 1 are sequentially switched by the gate control unit 2A into a selected state, and the TFT 13 connected to the gate line 11 in the selected state is turned ON. When the TFT 13 is turned ON, a signal according to the charges obtained by the conversion by the photodiode 12 is output through the source line 10 to the signal reading unit 2B.

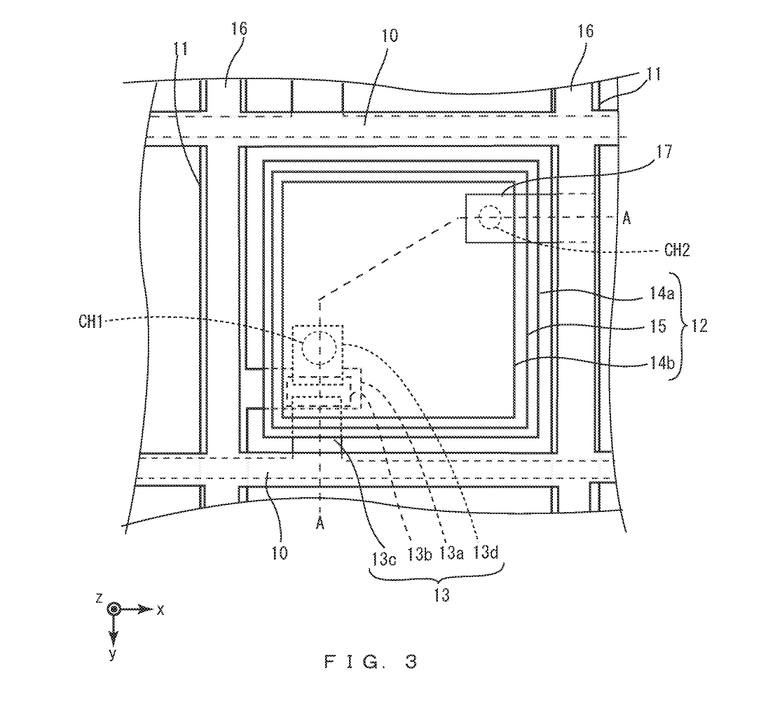

FIG. 3 is an enlarged plan view of one pixel portion of the imaging panel 1 shown in FIG. 2. As shown in FIG. 3, in the pixel surrounded by the gate lines 11 and the source lines 10, a lower electrode 14a, a photoelectric conversion layer 15, and an upper electrode 14b that compose the photodiode 12 are arranged so as to overlap with one another. Further, a bias line 16 is arranged so as to overlap with the gate line 11 and the source line 10 when viewed in a plan view. The bias line 16 supplies a bias voltage to the photodiode 12. The TFT 13 includes a gate electrode 13a integrated with the gate line 11, a semiconductor activity layer 13b, a source electrode 13c integrated with the source line 10, and a drain electrode 13d. In the pixel, a contact hole CH1 for connecting the drain electrode 13d and the lower electrode 14a with each other is provided. Further, in the pixel, a transparent conductive film 17 is provided so as to overlap with the bias line 16, and a contact hole CH2 for connecting the transparent conductive film 17 and the upper electrode 14b with each other is provided.

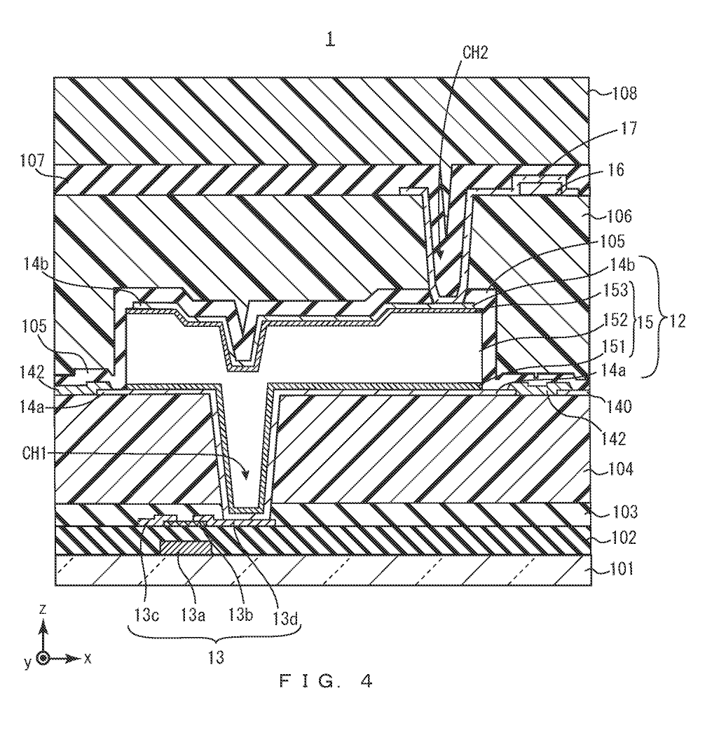

Here, FIG. 4 shows a cross-sectional view of the pixel shown in FIG. 3 taken along line A-A. As shown in FIG. 4, the TFT 13 is formed on the substrate 101. The substrate 101 is a substrate having insulating properties, such as a glass substrate, a silicon substrate, a plastic substrate having heat-resisting properties, or a resin substrate.

On the substrate 101, the gate electrode 13a integrated with the gate line 11 is formed. The gate electrode 13a and the gate line 11 are made of, for example, a metal such as aluminum (Al), tungsten (W), molybdenum (Mo), molybdenum nitride (MoN), tantalum (Ta), chromium (Cr), titanium (Ti), or copper (Cu), an alloy of any of these metals, or a metal nitride of these metals. In the present embodiment, the gate electrode 13a and the gate line 11 have a laminate structure in which a metal film made of molybdenum nitride and a metal film made of aluminum are laminated in this order. Regarding thicknesses of these metal films, for example, the metal film made of molybdenum nitride has a thickness of 100 nm, and the metal film made of aluminum has a thickness of 300 nm.

The gate insulating film 102 is formed on the substrate 101, and covers the gate electrode 13a. The gate insulating film 102 may be formed with, for example, silicon oxide (SiOₓ), silicon nitride (SiNₓ), silicon oxide nitride (SiOₓN_{y})(x>y), or silicon nitride oxide (SiNₓO_{y})(x>y). In the present embodiment, the gate insulating film 102 is formed with a laminate film obtained by laminating silicon oxide (SiOₓ) and silicon nitride (SiNₓ) in the order, and regarding the thicknesses of these films, the film of silicon oxide (SiOₓ) has a thickness of 50 nm, and the film of silicon nitride (SiNₓ) has a thickness of 400 nm.

The semiconductor activity layer 13b, as well as the source electrode 13c and the drain electrode 13d connected with the semiconductor activity layer 13b are formed on the gate electrode 13a with the gate insulating film 102 being interposed therebetween.

The semiconductor activity layer 13b is formed in contact with the gate insulating film 102. The semiconductor activity layer 13b is made of an oxide semiconductor. For forming the oxide semiconductor, for example, the following material may be used: InGaO₃(ZnO)₅; magnesium zinc oxide (MgₓZn₁₋ₓO); cadmium zinc oxide (CdₓZn₁₋ₓO); cadmium oxide (CdO); or an amorphous oxide semiconductor containing indium (In), gallium (Ga), and zinc (Zn) at a predetermined ratio. In the present embodiment, the semiconductor activity layer 13b is made of an amorphous oxide semiconductor containing indium (In), gallium (Ga), and zinc (Zn) at a predetermined ratio, and has a thickness of, for example, 70 nm.

The source electrode 13c and the drain electrode 13d are formed in contact with the semiconductor activity layer 13b and the gate insulating film 102. The source electrode 13c is integrated with the source line 10. The drain electrode 13d is connected with the lower electrode 14a through the contact hole CH1.

The source electrode 13c and the drain electrode 13d are formed in the same layer, and are made of, for example, a metal such as aluminum (Al), tungsten (W), molybdenum (Mo), tantalum (Ta), chromium (Cr), titanium (Ti), or copper (Cu), or alternatively, an alloy of any of these, of a metal nitride of any of these. Further, as the material for the source electrode 13c and the drain electrode 13d, the following material may be used: a material having translucency such as indium tin oxide (ITO), indium zinc oxide (IZO), indium tin oxide (ITSO) containing silicon oxide, indium oxide (In₂O₃), tin oxide (SnO₂), zinc oxide (ZnO), or titanium nitride; or a material obtained by appropriately combining any of these.

The source electrode 13c and the drain electrode 13d may be, for example, a laminate of a plurality of metal films. More specifically, the source electrode 13c, the source line 10, and the drain electrode 13d have a laminate structure in which a metal film made of molybdenum nitride (MoN), a metal film made of aluminum (Al), and a metal film made of molybdenum nitride (MoN) are laminated in this order. Regarding the thicknesses of the films, the metal film in the lower layer, which is made of molybdenum nitride (MoN), has a thickness of 100 nm, the metal film made of aluminum (Al) has a thickness of 500 nm, and the metal film in the upper layer, which is made of molybdenum nitride (MoN), has a thickness of 50 nm.

A first insulating film 103 is provided so as to cover the source electrode 13c and the drain electrode 13d. The first insulating film 103 may have a single layer structure made of silicon oxide (SiO₂) or silicon nitride (SiN), or a laminate structure obtained by laminating silicon nitride (SiN) and silicon oxide (SiO₂) in this order.

On the first insulating film 103, a second insulating film 104 is formed. The second insulating film 104 is made of an organic transparent resin, for example, acrylic resin or siloxane-based resin, and has a thickness of, for example, 2.5 μm.

On the drain electrode 13d, the contact hole CH1 is formed, which passes through the second insulating film 104 and the first insulating film 103.

On the second insulating film 104, the lower electrode 14a, which is connected with the drain electrode 13d through the contact hole CH1, is formed. The lower electrode 14a is formed with, for example, a metal film obtained by laminating molybdenum (Mo), aluminum (Al), and molybdenum (Mo), These metal films have thicknesses of, for example, 50 nm, 150 nm, and 100 nm, respectively, in the order from the lower layer.

A side end portion of the lower electrode 14a, at an end in the X-axis direction, is covered with a protection film 142. The protection film 142 is formed with, for example, an inorganic insulating film made of silicon nitride (SiN) in this example.

Further, on the lower electrode 14a, the photoelectric conversion layer 15 having a width in the X-axis direction that is smaller than that of the lower electrode 14a is formed at such a position that the photoelectric conversion layer 15 does not overlap with the protection film 142, The photoelectric conversion layer 15 has a PIN structure that is obtained by laminating the n-type amorphous semiconductor layer 151, the intrinsic amorphous semiconductor layer 152, and the p-type amorphous semiconductor layer 153 in the order.

The n-type amorphous semiconductor layer 151 is made of amorphous silicon doped with an n-type impurity (for example, phosphorus). The n-type amorphous semiconductor layer 151 has a thickness of, for example, 30 nm.

The intrinsic amorphous semiconductor layer 152 is made of intrinsic amorphous silicon. The intrinsic amorphous semiconductor layer 152 is formed in contact with the n-type amorphous semiconductor layer 151. The intrinsic amorphous semiconductor layer has a thickness of, for example, 1000 nm.

The p-type amorphous semiconductor layer 153 is made of amorphous silicon doped with a p-type impurity (for example, boron). The p-type amorphous semiconductor layer 153 is formed in contact with the intrinsic amorphous semiconductor layer 152. The p-type amorphous semiconductor layer 153 has a thickness of, for example, 5 nm.

On the p-type amorphous semiconductor layer 153, the upper electrode 14b is formed. The upper electrode 14b has a width in the X-axis direction that is smaller than that of the photoelectric conversion layer 15, The upper electrode 14b is made of, for example, indium tin oxide (ITO), and has a thickness of, for example, 70 nm.

A third insulating film 105 is formed so as to cover the protection film 142 and the photodiode 12. The third insulating film 105 is, for example, an inorganic insulating film made of silicon nitride (SiN), and has a thickness of, for example, 300 nm.

In the third insulating film 105, a contact hole CH2 is formed at such a position that the contact hole CH2 overlaps with the upper electrode 14b. On the third insulating film 105, in an area thereof except for the contact hole CH2, a fourth insulating film 106 is formed. The fourth insulating film 106 is formed with an organic transparent resin made of, for example, acrylic resin or siloxane-based resin, and has a thickness of, for example, 2.5 μm.

On the fourth insulating film 106, the bias line 16 is formed. Further, on the fourth insulating film 106, the transparent conductive film 17 is formed so as to overlap with the bias line 16. The transparent conductive film 17 is in contact with the upper electrode 14b at the contact hole CH2. The bias line 16 is connected to the control unit 2 (see FIG. 1). The bias line 16 applies a bias voltage through the contact hole CH2 to the upper electrode 14b, the bias voltage being input from the control unit 2. The bias line 16 has a laminate structure that is obtained by laminating, for example, a metal film made of molybdenum nitride (MoN), a metal film made of aluminum (Al), and a metal film made of titanium (Ti) in this order. The films of molybdenum nitride (MoN), aluminum (Al), and titanium (Ti) have thicknesses of, for example, 100 nm, 300 nm, and 50 nm, respectively.

On the fourth insulating film 106, a fifth insulating film 107 is formed so as to cover the transparent conductive film 17. The fifth insulating film 107 is an inorganic insulating film made of, for example, silicon nitride (SiN), and has a thickness of, for example, 200 nm.

On the fifth insulating film 107, a sixth insulating film 108 is formed. The sixth insulating film 108 is made of, for example, an organic transparent resin such as acrylic resin or siloxane-based resin, and has a thickness of, for example, 2.0 μm.

### (Method for Producing Imaging Panel 1)

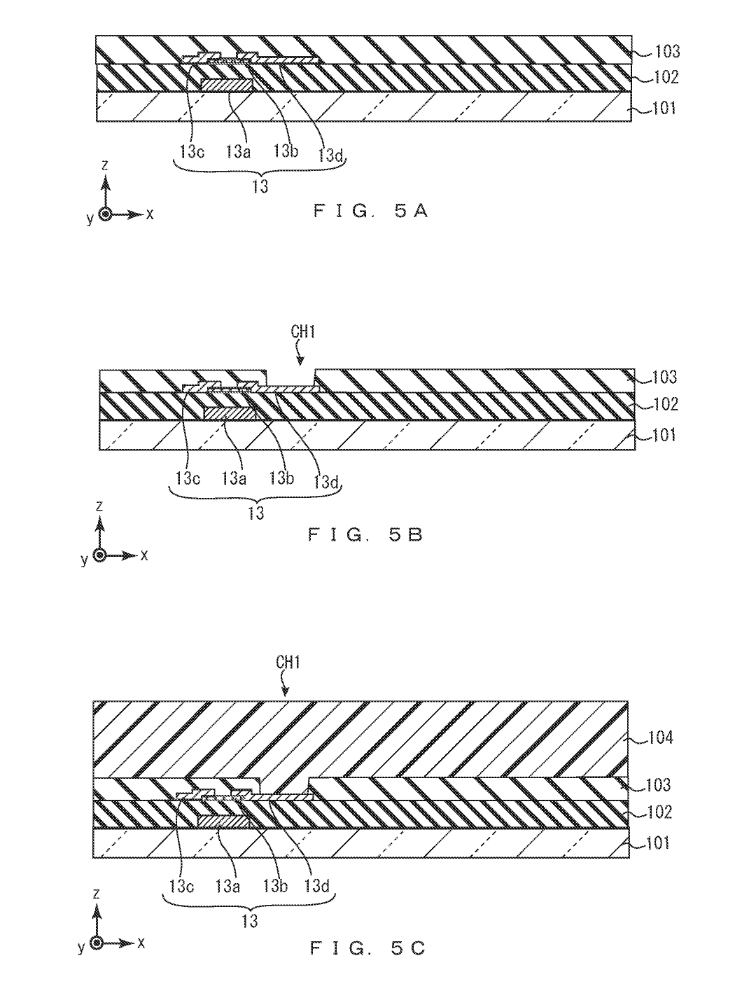

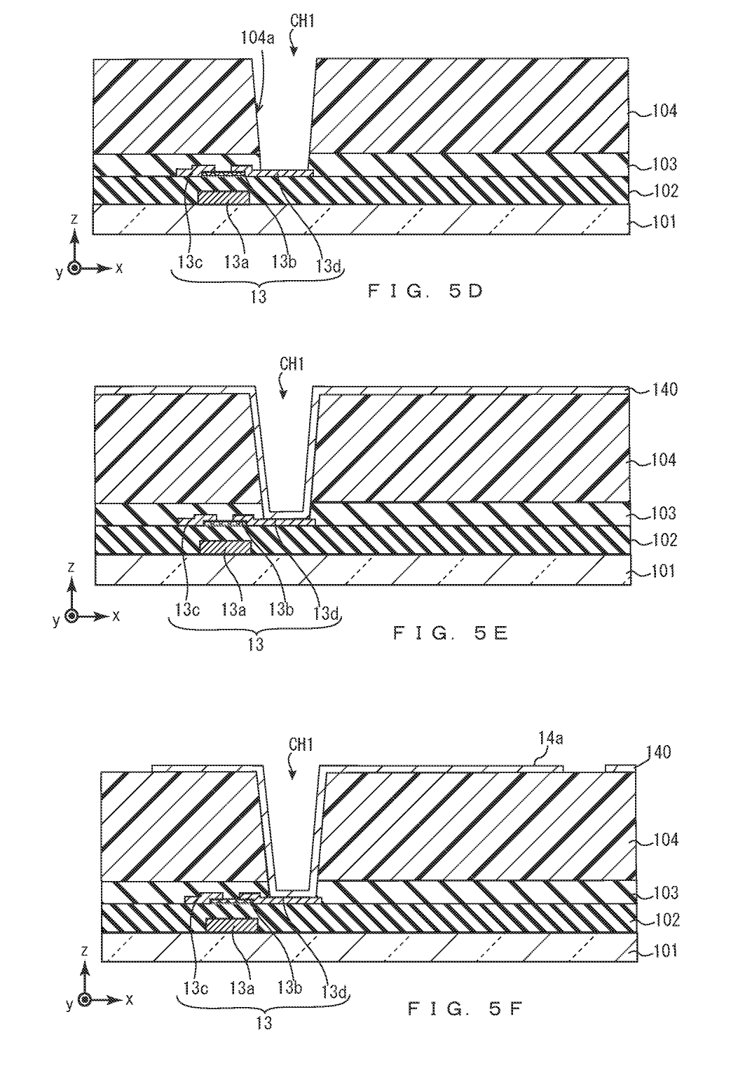

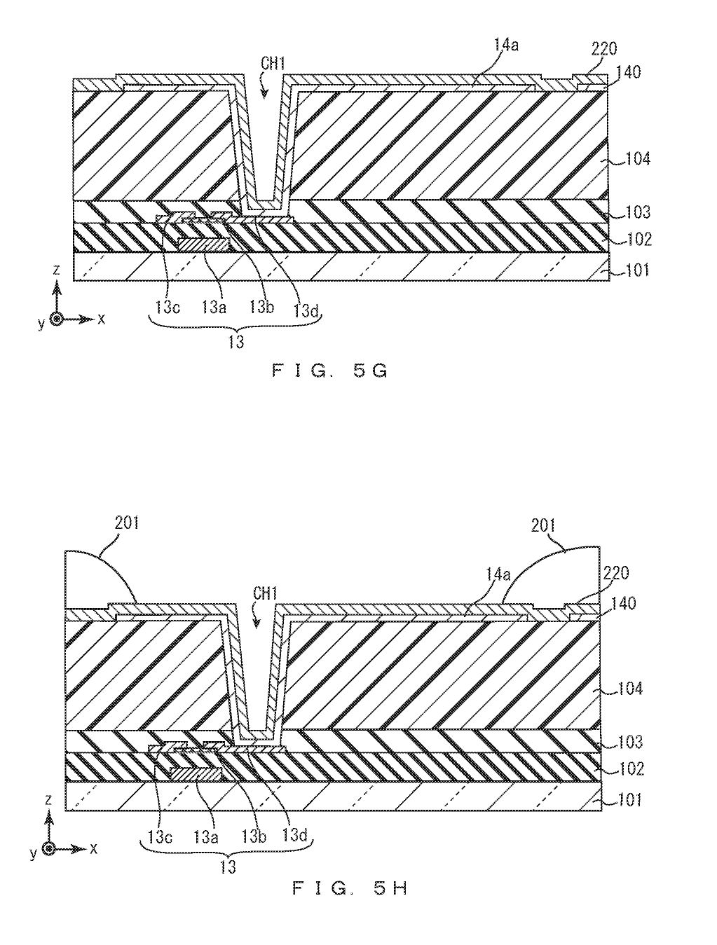

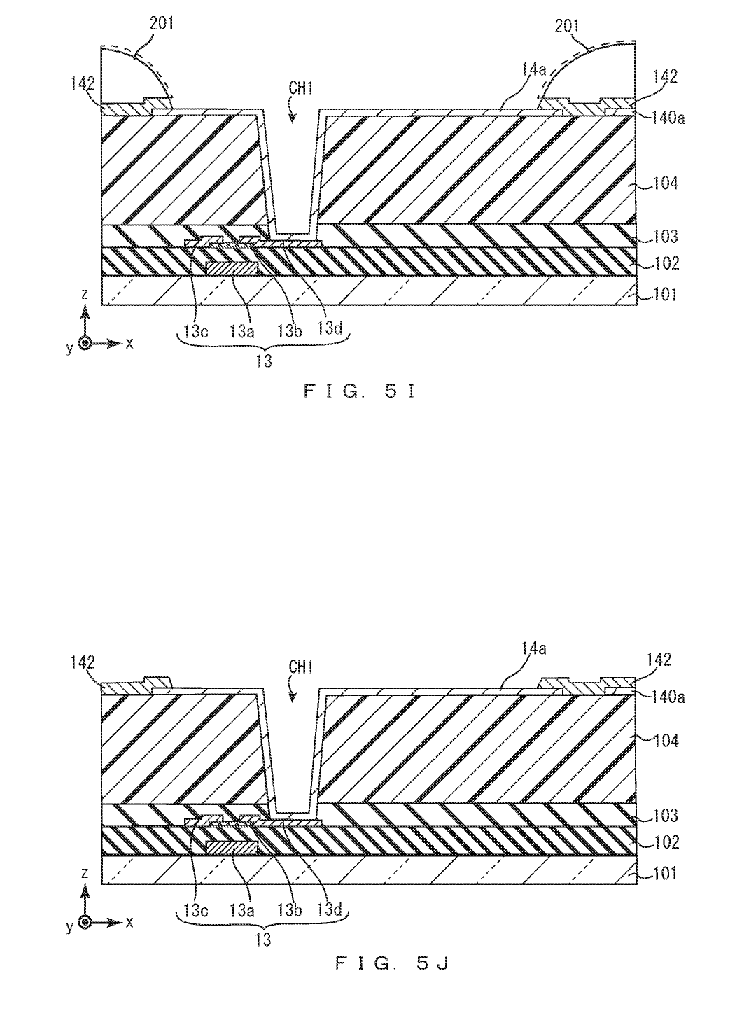

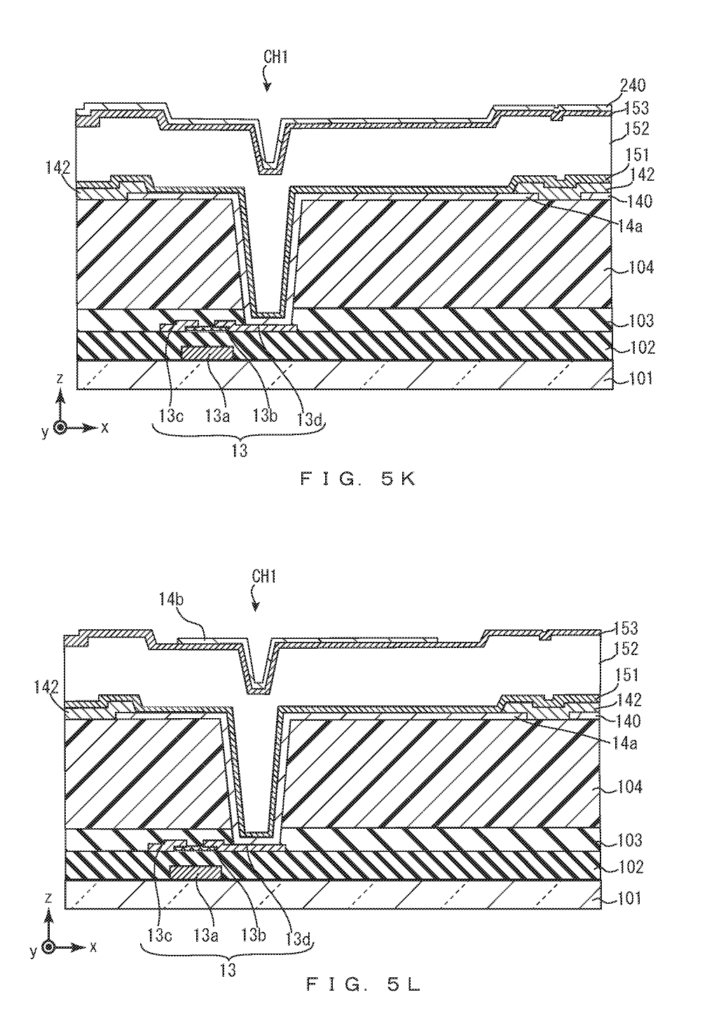

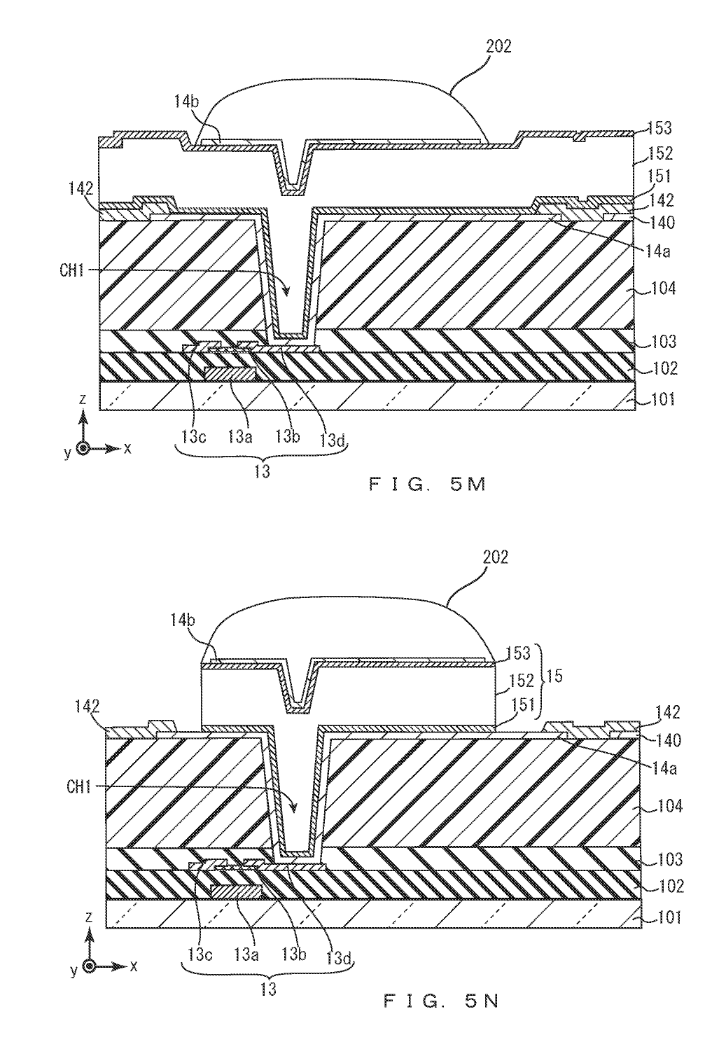

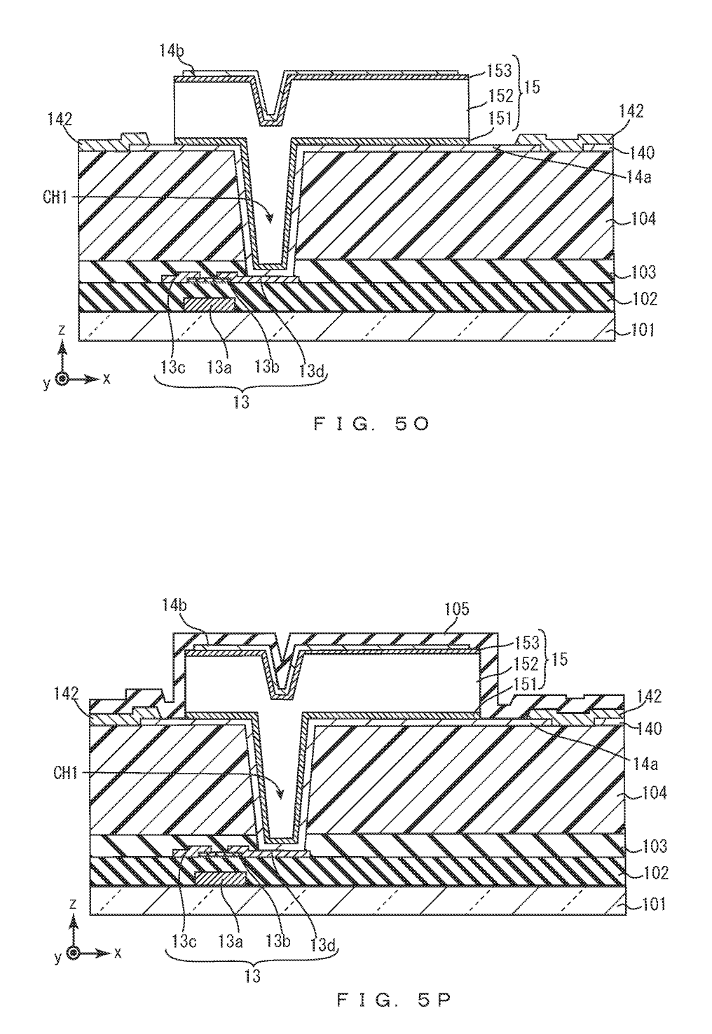

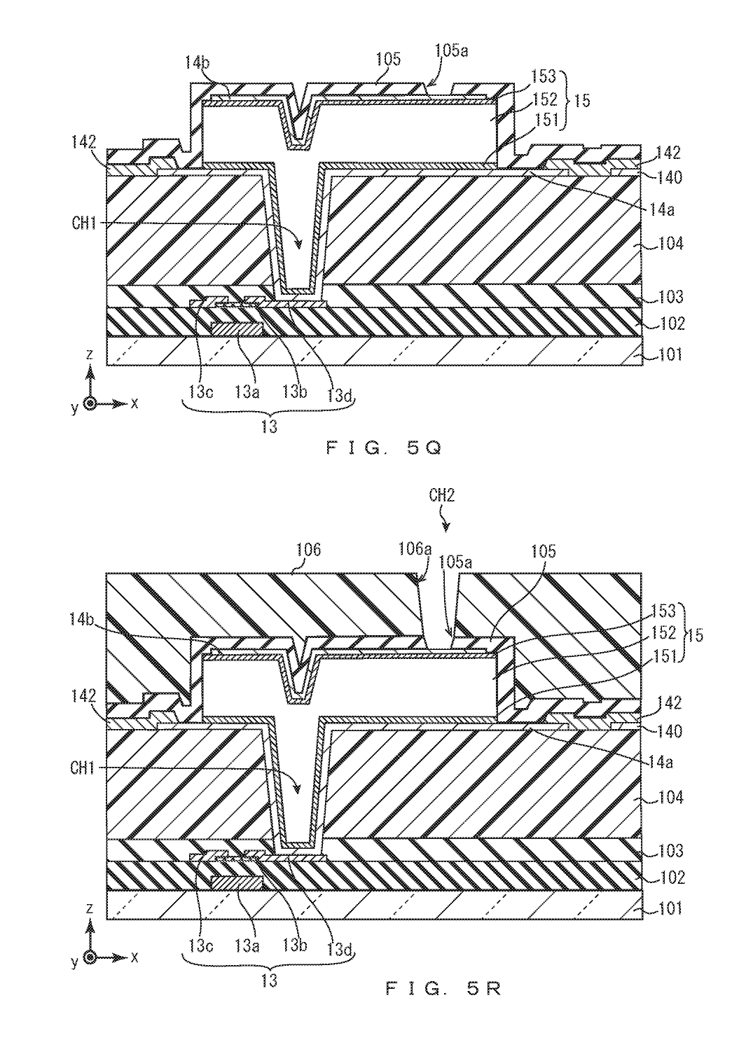

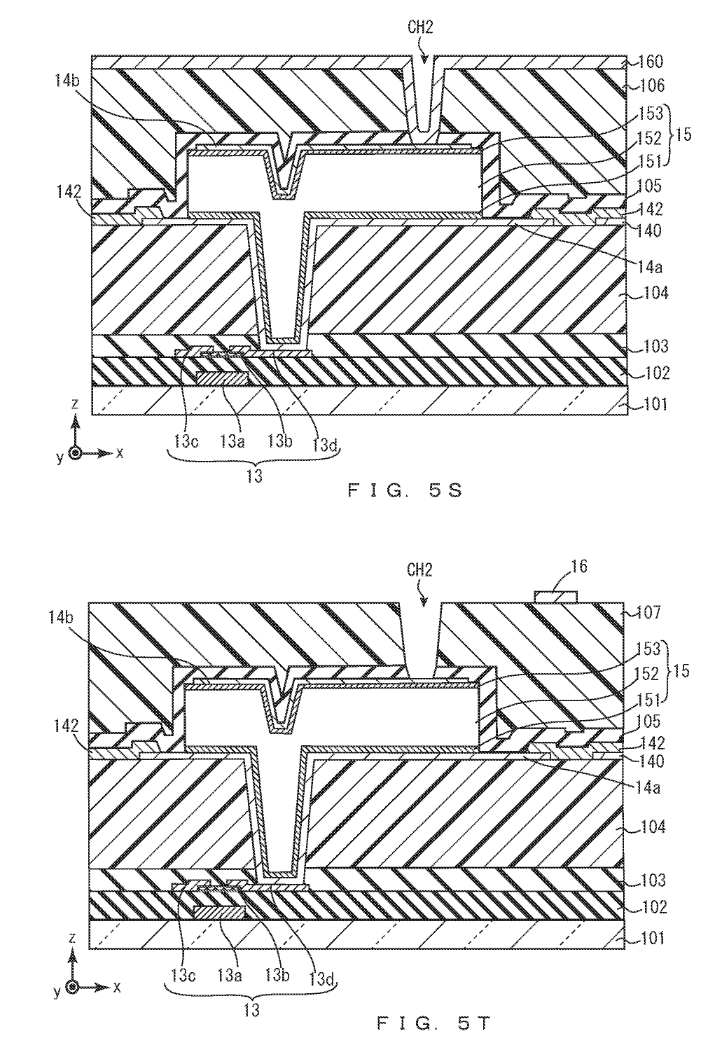

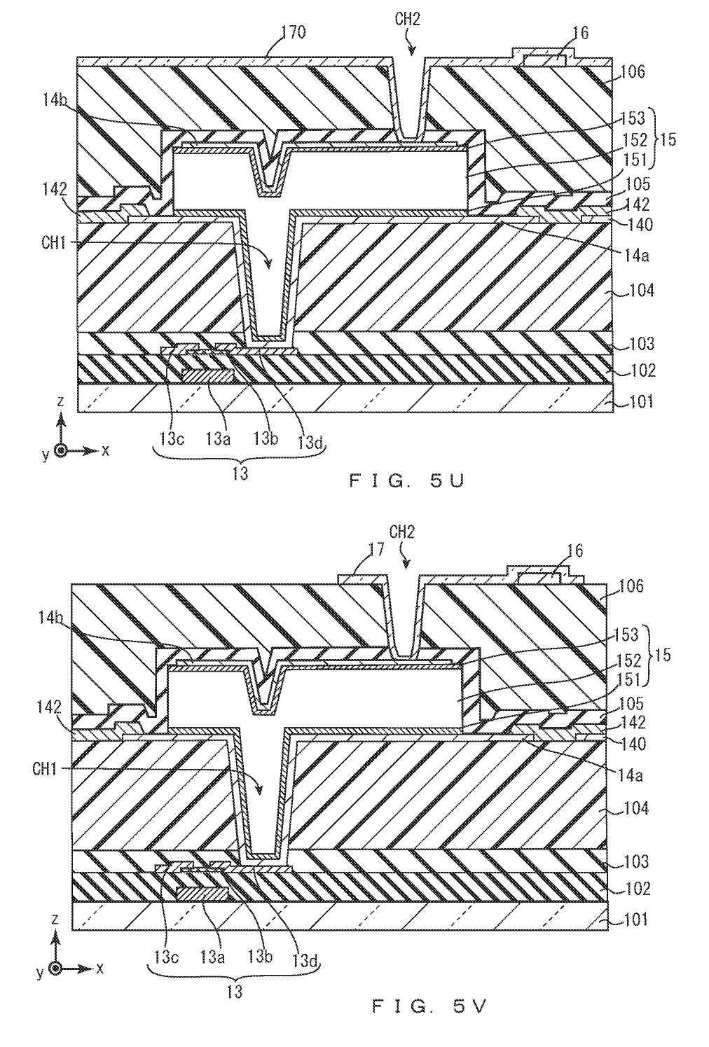

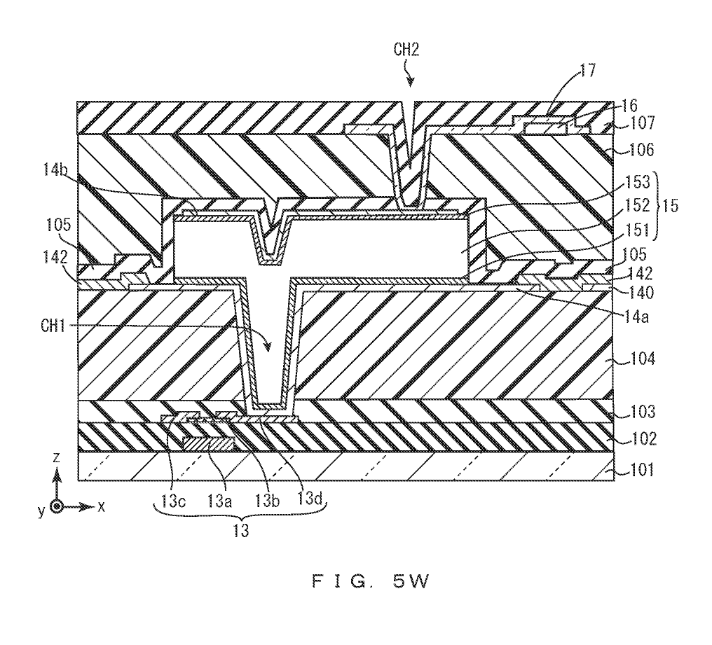

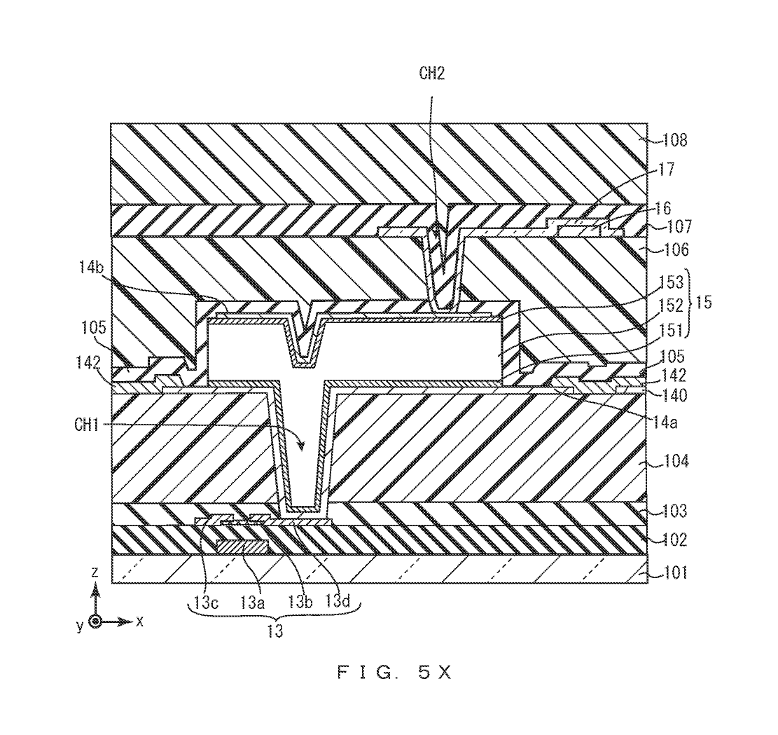

Next, the following description describes a method for producing the imaging panel 1. FIGS. 5A to 5X are cross-sectional views of the pixel taken along line A-A in respective steps of the method for producing the imaging panel 1 (see FIG. 3).

As shown in FIG. 5A, the gate insulating film 102 and the TFT 13 are formed on the substrate 101 by a known method, and the insulating film 103 made of silicon nitride (SiN) is formed by, for example, plasma CVD, so as to cover the TFT 13.

Subsequently, a heat treatment at about 350° C. is applied to an entire surface of the substrate 101, and photolithography and wet etching are carried out so that the first insulating film 103 is patterned, whereby a contact hole CH1 is formed on the drain electrode 13d (see FIG. 5B).

Next, the second insulating film 104 made of acrylic resin or siloxane-based resin is formed on the first insulating film 103 by, for example, slit coating (see FIG. 5C).

Then, an opening 104a of the second insulating film 104 is formed by photolithography on the contact hole CH1 (see FIG. 5D).

Subsequently, on the second insulating film 104, a metal film 140 obtained by laminating molybdenum (Mo), aluminum (Al), and molybdenum (Mo) in the order by, for example, sputtering is formed (see FIG. 5E),

Then, photolithography and wet etching are carried out, whereby the metal film 140 is patterned. Through these steps, on the second insulating film 104, there are formed the lower electrode 14a that is connected with the drain electrode 13d through the contact hole CH1, and the metal film 140 that is arranged so as to be apart from the lower electrode 14a (see FIG. 5F).

Subsequently, on the second insulating film 104, an inorganic insulating film 220 made of silicon nitride (SiN) is formed by, for example, plasma CVD so as to cover the lower electrode 14a and the metal film 140 (see FIG. 5G).

Thereafter, on the inorganic insulating film 220, a resist 201 is formed by photolithography in the vicinities of the side end portions of the lower electrode 14a and at such a position that the resist 201 overlaps with the metal film 140 (see FIG. 5H). Here, the resist 201 has a tapered shape.

Then, dry etching is carried out so as to remove, by etching, a part of the inorganic insulating film 220 that is not covered with the resist 201 (see FIG. 5I). Through these steps, a protection film 142 that covers the side end portions of the lower electrode 14a and the side end portions of the metal film 140 is formed. Incidentally, the side surface of the resist 201 is etched inward by dry etching, whereby the protection film 142 has a tapered shape. The taper angle of the protection film 142 is, for example, 70° or less preferably.

Thereafter, the resist 201 is removed (see FIG. 5J).

Next, the n-type amorphous semiconductor layer 151, the intrinsic amorphous semiconductor layer 152, and the p-type amorphous semiconductor layer 153 are formed in the stated order by, for example, plasma CVD, so as to cover the protection film 142 and the lower electrode 14a. Then, on the p-type amorphous semiconductor layer 153, a transparent conductive film 240 made of, for example, ITO is formed (see FIG. 5K).

Subsequently, photolithography and dry etching are carried out so as to pattern the transparent conductive film 240, whereby the upper electrode 14b is formed on the p-type amorphous semiconductor layer 153 (see FIG. 5L).

Subsequently, on the p-type amorphous semiconductor layer 153, a resist 202 is formed by, for example, plasma CVD so as to cover the upper electrode 14b (see FIG. 5M).

Then, dry etching is carried out for the patterning of the n-type amorphous semiconductor layer 151 the intrinsic amorphous semiconductor layer 152, and the p-type amorphous semiconductor layer 153, in which parts thereof not covered with the resist 202 are removed. Through these steps, the photoelectric conversion layer 15 having a width in the X-axis direction that is smaller than that of the lower electrode 14a is formed. Thereafter, to decrease leakage current in the photoelectric conversion layer 15, the surface of the photoelectric conversion layer 15 is subjected to a cleaning treatment with use of hydrogen fluoride (see FIG. 5N). The side end portions of the lower electrode 14a and the metal film 140, which are covered with the protection film 142, are not exposed to hydrogen fluoride. For this reason, aluminum contained in the lower electrode 14a is not dissolved by the cleaning treatment with use of hydrogen fluoride, and metal ions do not adhere to the side surface of the photoelectric conversion layer 15. As a result, leakage current in the photoelectric conversion layer 15 is decreased.

Next, the resist 202 is removed (see FIG. 5O), and the third insulating film 105 made of silicon nitride (SiN) is formed by, for example, plasma CVD, so as to cover the protection film 142, the upper electrode 14b, the lower electrode 14a, and the photoelectric conversion layer 15 (see FIG. 5P).

Then, photolithography and wet etching are carried out, whereby an opening 105a of the third insulating film 105 is formed (see FIG. 5O).

Subsequently, the fourth insulating film 106 made of acrylic resin or siloxane-based resin is formed by, for example, slit-coating on the third insulating film 105. Then, by photolithography, an opening 106a of the fourth insulating film 106 is formed on the opening 105a (see FIG. 5R). Through these steps, the contact hole CH2 composed of the openings 105a and 106a is formed.

Next, a metal film 160 obtained by laminating molybdenum nitride (MoN), aluminum (Al), and titanium (Ti) in this order is formed on the fourth insulating film 106 by, for example, sputtering (see FIG. 5S).

Then, photolithography and wet etching are carried out so as to pattern the metal film 160, whereby the bias line 16 is formed (see FIG. 5T).

Subsequently, the transparent conductive film 170 made of ITO is formed on the fourth insulating film 106 by, for example, sputtering so as to cover the bias line 16 (see FIG. 5U).

Then, photolithography and dry etching are carried out, whereby the transparent conductive film 170 is patterned, whereby the transparent conductive film 17 that is connected with the bias line 16 and is connected with the upper electrode 14b through the contact hole CH2 is formed (see FIG. 5V).

Next, on the fourth insulating film 106, the fifth insulating film 107 made of silicon nitride (SiN) is formed by, for example, plasma CVD so as to cover the transparent conductive film 17 (see FIG. 5W).

Subsequently, the sixth insulating film 108 made of acrylic resin or siloxane-based resin is formed on the fifth insulating film 107 by, for example, slit-coating (see FIG. 5X).

The method for producing the imaging panel 1 in Embodiment 1 is as described above. The side end portion of the lower electrode 14a is covered with the protection film 142, as described above. For this reason, even if a cleaning treatment with use of hydrogen fluoride is carried out after the photoelectric conversion layer 15 is formed, the lower electrode 14a is not exposed to hydrogen fluoride, and ions of aluminum contained in the lower electrode 14a do not adhere to the side surface of the photoelectric conversion layer 15. With this configuration, therefore, it is possible to decrease the occurrence of leakage current in the photoelectric conversion layer 15

Further, forming the protection film 142 in a tapered shape makes it sure that no part of the semiconductor layer should remain unetched when the etching for forming the photoelectric conversion layer 15 is carried out. In a case where the protection film 142 is not in a tapered shape, the side wall of the protection film 142 is approximately perpendicular to the lower electrode 14a, and portions of the photoelectric conversion layer 15 in the vicinities of the side wall tend to be thicker than portions thereof in the other area. Further, as the etching method, dry etching, which is anisotropic etching, is used. In a case where the protection film 142 is not in a tapered shape, a part of the n-type amorphous semiconductor layer 153 in the vicinity of the side wall of the protection film 142, or a part of the n-type amorphous semiconductor layer 153 and the intrinsic amorphous semiconductor layer 152, tend to remain unetched. The portions of the semiconductor layer that remain unetched tend to come off and become particles, which cause defects, thereby causing decreases in the yield.

Further, in a cleaning treatment with use of hydrogen fluoride, the protection film 142 is etched with hydrogen fluoride, thereby having the thickness reduced. In a case where the photoelectric conversion layer 15 and the protection film 142 overlap with each other, the decrease in the thickness of the protection film 142 causes a clearance to be formed between the photoelectric conversion layer 15 and the protection film 142. As a result, a state can arise in which the photoelectric conversion layer 15 is not completely covered with the third insulating film 105. In this case, the photoelectric conversion layer 15 can be easily contaminated, which can cause a leakage path to be formed; this can result in that leakage current tends to be generated in the photoelectric conversion layer 15. In Embodiment 1, since the photoelectric conversion layer 15 and the protection film 142 do not overlap with each other, the photoelectric conversion layer 15 can be completely covered with the third insulating film 105. This makes it possible to decrease the occurrence of leakage current in the photoelectric conversion layer 15.

### (Operation of X-Ray Imaging Device 100)

Here, operations of the X-ray imaging device 100 shown in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 are transmitted through an object S, and are incident on the scintillator 1A. The X-rays incident on the scintillator 1A are converted into fluorescence (scintillation light), and the scintillation light is incident on the imaging panel 1. When the scintillation light is incident on the photodiode 12 provided in each pixel in the imaging panel 1, the scintillation light is changed to charges by the photodiode 12 in accordance with the amount of the light. A signal according to the charges obtained by conversion by the photodiode 12 is read out through the source line 10 to the signal reading unit 2B (see FIG. 2 and the like) when the TFT 13 (see FIG. 3 and the like) is in the ON state according to a gate voltage (positive voltage) that is output from the gate control unit 2A through the gate line 11. Then, an X-ray image in accordance with the signal thus read out is generated in the control unit 2.

### EMBODIMENT 2

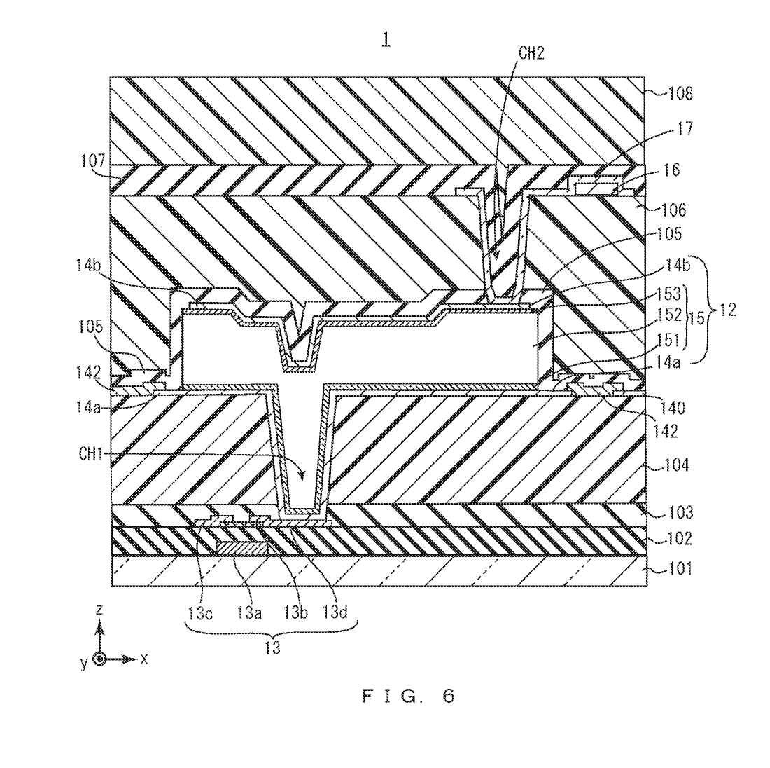

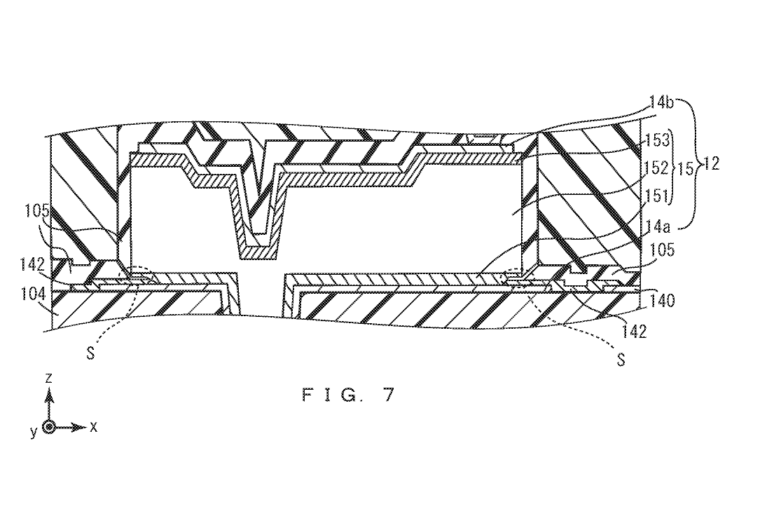

Embodiment 1 described above is explained with reference to an exemplary case where the protection film 142 is in a tapered shape, but as shown in FIG. 6, the protection film 142 does not have to be in a tapered shape.

Besides, Embodiment 1 described above is explained with reference to an exemplary case where the protection film 142 is made of silicon nitride (SiN), but the material of the protection film 142 is not limited to this. The protection film 142 may be made of silicon oxide (SiO₂), or alternatively, silicon oxide nitride (SiON).

Further, silicon nitride (SiN), silicon oxide (SiO₂), and silicon oxide nitride (SiON) are etched to different levels by immersion in hydrogen fluoride, respectively. In other words, the relationship of the etched amounts of silicon nitride (SiN), silicon oxide (SiO₂), and silicon oxide nitride (SiON) in immersion in hydrogen fluoride is as follows: silicon nitride (SiN)<silicon oxide (SiO₂)<silicon oxide nitride (SiON). In any case where any one of these materials is used, the thickness of the film when it is formed is set with the amount of etching caused by immersion in hydrogen fluoride being taken into consideration.

Even in a case where silicon oxide (SiO₂) or silicon oxide nitride (SiON) is used as a material of the protection film 142, aluminum contained in the lower electrode 14a is not dissolved by the cleaning treatment with use of hydrogen fluoride, since the side end portion of the lower electrode 14a is covered with the protection film 142, Leakage current in the photoelectric conversion layer 15, therefore, can be decreased, as is the case with Embodiment 1.

Embodiments of the present invention are described in detail above, but these are merely examples for implementing the present invention. The present invention, therefore, is not limited to the above-described embodiments, and the above-described embodiment can be appropriately varied and implemented without departing from the spirit and scope of the invention.

(1) Embodiments 1 and 2 described above are explained with reference to an exemplary case where the protection film 142 is provided a such position that the protection film 142 does not overlap with the photoelectric conversion layer 15, but the configuration may be such as follows. FIG. 7 is a partial cross-sectional view of an imaging panel in the present modification example, in which structural portions different from those in the above-described embodiments are principally shown. In FIG. 7, the same configurations as those in the above-described embodiments are denoted by the same reference symbols as those in the above-described embodiments.

As shown in FIG. 7, in the present modification example, the protection film 142 and the photoelectric conversion layer 15 are arranged so as to partially overlap with each other. Besides, as shown in the broken line frame S in FIG. 7, a clearance is formed between the protection film 142 and the photoelectric conversion layer 15. This is caused by the cleaning treatment with use of hydrogen fluoride after the photoelectric conversion layer 15 is formed, which reduces the thickness of the protection film 142 and causes the photoelectric conversion layer 15 to be formed in an inversely tapered shape. The clearance formed between the protection film 142 and the photoelectric conversion layer 15 results in that the photoelectric conversion layer 15 is not completely covered with the third insulating film 105, and the photoelectric conversion layer 15 tends to be easily contaminated. In this case, however, aluminum contained in the lower electrode 14a is not dissolved due to hydrogen fluoride, since the side end portion of the lower electrode 14a is covered with the protection film 142, and this configuration makes it possible to prevent aluminum from adhering to the surface of the photoelectric conversion layer 15.

1. An imaging panel that generates an image based on scintillation light that is obtained from X-rays transmitted through an object, the imaging panel comprising:
a substrate;
a thin film transistor formed on the substrate;
an insulating film that covers the thin film transistor;
a photoelectric conversion layer that is provided on the insulating film and converts the scintillation light into charges;
an upper electrode provided on the photoelectric conversion layer;
a lower electrode that is provided under the photoelectric conversion layer and is connected with the thin film transistor; and
a protection film that covers a side end portion of the lower electrode.

2. The imaging panel according to claim 1, further comprising:
an inorganic insulating film that covers the upper electrode, the photoelectric conversion layer, and the protection film,
wherein the protection film is provided at such a position that the protection film does not overlap with the photoelectric conversion layer.

3. The imaging panel according to claim 1,
wherein the protection film is made of silicon nitride.

4. The imaging panel according to claim 1,
wherein the protection film is made of silicon oxide.

5. The imaging panel according to claim 1,
wherein the protection film is made of silicon oxide nitride.

6. A method for producing an imaging panel that generates an image based on scintillation light that is obtained from X-rays transmitted through an object, the producing method comprising the steps of:
forming a thin film transistor on a substrate;
forming a first insulating film and a second insulating film on the thin film transistor;
forming a first contact hole on a drain electrode of the thin film transistor, the first contact hole passing through the first insulating film and the second insulating film;
forming a lower electrode on the second insulating film, the lower electrode being connected with the drain electrode through the first contact hole;
forming a protection film that covers a side end portion of the lower electrode;
forming a first semiconductor layer of a first conductive type, an intrinsic amorphous semiconductor layer, and a second semiconductor layer of a second conductive type that is opposite to the first conductive type, in the stated order, as a photoelectric conversion layer, so that the photoelectric conversion layer covers the lower electrode and the protection film;
forming an upper electrode on the second semiconductor layer;
applying a resist on the second semiconductor layer so that the resist covers the upper electrode, and etching the first semiconductor layer, the intrinsic amorphous semiconductor layer, and the second semiconductor layer, thereby forming the photoelectric conversion layer; and
carrying out a cleaning treatment with use of hydrogen fluoride with respect to a surface of the photoelectric conversion layer formed.

7. The producing method according to claim 6,
wherein the protection film is provided at such a position that the protection film does not overlap with the photoelectric conversion layer,
the producing method further comprising the step of:
forming a third insulating film after the cleaning treatment, the third insulating film covering the upper electrode, the photoelectric conversion layer, and the protection film.
